(19) United States
(12) Patent Application Publication
(10) Pub. No.: US 2006/0181220 A1
(43) Pub. Date: Aug. 17, 2006

(54) Apparatus and method of fabricating emitter using arc

(75) Inventors: Chang-wook Moon, Seoul (KR); In-kyeong Yoo, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Suwoni-si (KR)

(21) Appl. No.: 11/254,793

(22) Filed: Oct. 21, 2005

(30) Foreign Application Priority Data
Feb. 17, 2005 (KR) 10-2005-0013139

(51) Int. Cl. H01L 21/00; H01J 7/24

(52) U.S. Cl. 315/111.21; 438/20

(57) ABSTRACT

A method and apparatus for fabricating an emitter by colliding an arc with the surface of a wafer inside a vacuum chamber are provided. The apparatus includes: a vacuum chamber in which a wafer is inserted; a magnetic field generating unit for generating a uniform magnetic field inside the vacuum chamber; an electric field generating unit for forming an electric field parallel to the magnetic field inside the vacuum chamber; and a master emitter for emitting electrons towards the wafer. The electrons emitted from the master emitter move along the magnetic field and the electric field. The arc is generated when the electric field or the driving voltage surpasses a threshold by controlling the strength of the electric field and the driving voltage of the master emitter. Thus, the surface of the wafer is instantaneously melted and solidified by the arc, thereby forming the emitter with a sharp tip on the surface of the wafer.

This application claims the priority of Korean Patent Application No. 10-2005-0013139, filed on Feb. 17, 2005 in the Korean Intellectual Property Office, the disclosure of which is incorporated herein in its entirety by reference.

### BACKGROUND OF THE DISCLOSURE

### 1. Field of the Disclosure

The disclosure relates to an apparatus and method of fabricating an emitter using an arc, and more particularly, to an apparatus and method of fabricating an emitter, which is formed by colliding an arc with the surface of a wafer inside a vacuum chamber.

2. Description of the Related Art

A next generation display device, for example, a field emission device (FED) uses a metal emitter having an extremely sharp tip of a nano-size. FIG. 1 is an exemplary view of a conventional FED using a metal emitter 13 of this type. As illustrated in FIG. 1, an insulating layer 11 having an opening is formed in a substrate 10 in the FED. A gate 12 is formed on top of the insulating layer 11, and the metal emitter 13 is formed inside the opening formed in the insulating layer 11. A complex fabrication process is performed in order to make the tip of the metal emitter 13 extremely sharp.

FIGS. 2A through 2C are exemplary views illustrating a conventional method of fabricating the metal emitter 13 having an extremely sharp tip. First, as illustrated in FIG. 2A, the insulating layer 11 is deposited on top of the substrate 10, and then the insulating layer 11 is patternized to form the opening. Then, as illustrated in FIG. 2B, a gate 12 is deposited on top of the insulating layer 11 while rotating the substrate 10 using a tilt deposition method. Here, the gate 12 is formed to protrude over the edges of the opening on the top surface of the insulating layer 11. Next, as illustrated in FIG. 2C, a metal layer 14 is deposited vertically on the top surface of the gate 12, and thus a portion of the metal passes through the gate 12, thereby forming the metal emitter 13 inside the opening of the insulating layer 11. In this process, since most of the metal is deposited in the center of the opening in the insulating layer 11 and less metal is deposited in the outer regions of the opening, a metal emitter 13 having a sharp tip can be formed. After the metal emitter 13 is formed as described above, the metal layer 14 is removed by etching. Then, a FED having the metal emitter 13 with a sharp tip as illustrated in FIG. 1 can be obtained.

Metal emitters used in various electric/electronic devices as electron emitters require a complex semiconductor fabricating process comprising several operations since the metal emitters require extremely sharp tips of nano-sizes in order to increase an electron emitting efficiency. Consequently, the manufacturing time and cost of metal emitters and electric/electronic devices using the metal emitters are increased. Furthermore, the tips of the emitters cannot be uniformly formed using the conventional method of fabricating the metal emitters.

### SUMMARY OF THE DISCLOSURE

The present invention may provide a simplified method of fabricating an emitter having a tip of a nano-size using an arc instead of a complex semiconductor manufacturing process.

The present invention also may provide an apparatus using an arc for fabricating an emitter having a tip of a nano-size.

According to an aspect of the present invention, there may be provided an apparatus for fabricating an emitter using an arc, the apparatus including: a vacuum chamber in which a wafer is inserted; a magnetic field generating unit for generating a uniform magnetic field inside the vacuum chamber; an electric field generating unit for forming an electric field parallel to the magnetic field inside the vacuum chamber; and a master emitter for emitting electrons towards the wafer. The arc is generated by the electrons emitted from the master emitter in the magnetic field and the electric field, the arc making the surface of the wafer to instantaneously melt and solidify, thereby forming the emitter with a sharp tip on the surface of the wafer.

According to an aspect, the magnetic field generating unit includes: a first magnetic pole disposed on the top portion of the vacuum chamber; and a second magnetic pole having an opposite polarity to the first magnetic pole, disposed on the bottom portion of the vacuum chamber facing the first magnetic pole.

Also, the electric field generating unit includes: a first top electrode and a first bottom electrode facing each other inside the magnetic field; and a first power source for applying a voltage between the first top electrode and the first bottom electrode. Here, the first power source applies a voltage in the range of approximately 1-10 kV between the first top electrode and the first bottom electrode. In addition, the wafer is disposed on surface of the first top electrode facing the first bottom electrode.

The master emitter includes: a substrate; a second bottom electrode formed on the substrate; an insulating layer formed on the second bottom electrode; a second top electrode formed on the insulating layer; a mask formed on the second top electrode; and a second power source for applying a voltage between the second bottom electrode and the second top electrode.

At least one opening arranged in a predetermined form is patterned on the mask, and the electrons are emitted from the second top electrode via the at least one opening.

Also, a thickness of the insulating layer is in the range of approximately 5-30 nm.

The master emitter having the above-described structure is placed on top of the first bottom electrode, facing the wafer. In this case, an isolating material is interposed between the master emitter and the first bottom electrode, thereby electrically insulating the master emitter and the first bottom electrode.

According to an aspect, the level of the voltage applied between the second bottom electrode and the second top electrode is increased until the arc is formed between the wafer and the second top electrode, while voltage between the first top electrode and the first bottom electrode is maintained constant.

The apparatus may further include an amperemeter for measuring a current between the second bottom electrode and the second top electrode to detect the creation of the arc.

According to another aspect of the present invention, there is provided a method of fabricating an emitter using an arc. The method includes: insulating a wafer inside a vacuum chamber; forming a parallel electric field and a magnetic field inside the vacuum chamber; emitting electrons from an electron emitting means towards the wafer inside the vacuum chamber; and forming the emitter with a sharp tip on the surface of the wafer by instantaneously melting and solidifying the surface of the wafer by the arc generated by the movement of the electrons emitted from the electron emitting means in the magnetic field and the electric field.

Here, the magnetic field is formed by a first magnetic pole disposed at the top portion of the vacuum chamber and a second magnetic pole having an opposite polarity to the first magnetic pole, disposed at the bottom portion of the vacuum chamber facing the first magnetic pole. The electric field is formed by applying a voltage between a first top electrode and a first bottom electrode facing each other inside the magnetic field.

In the present structure, a voltage applied between the second bottom electrode and the second top electrode is increased until an arc is formed between the wafer and the second top electrode. The voltage applied between the second bottom electrode and the second top electrode is stopped immediately after the arc is generated between the wafer and the second top electrode. Whether or not the arc is generated between the wafer and the second top electrode can be detected by observing the current flowing between the second bottom electrode and the second top electrode.

### BRIEF DESCRIPTION OF THE DRAWINGS

The above and other features and advantages of the present invention are described in exemplary embodiments thereof with reference to the attached drawings in which:

FIG. 1 is an exemplary view of a conventional field emission device (FED) using a metal emitter;

FIGS. 2A through 2C are exemplary views illustrating a conventional method of fabricating the metal emitter of FIG. 1;

FIG. 3 is a cross section of an apparatus for fabricating an emitter according to an embodiment of the present invention;

FIG. 4 is a cross section of an exemplary view of the emitter fabricated using a method of fabricating the emitter according to an embodiment of the present invention;

FIG. 5 is a photograph of the top view of the emitter fabricated using the method of fabricating the emitter according to an embodiment of the present invention; and

FIG. 6 is a schematic graph illustrating voltage-current characteristics of a master emitter according to an embodiment of the present invention.

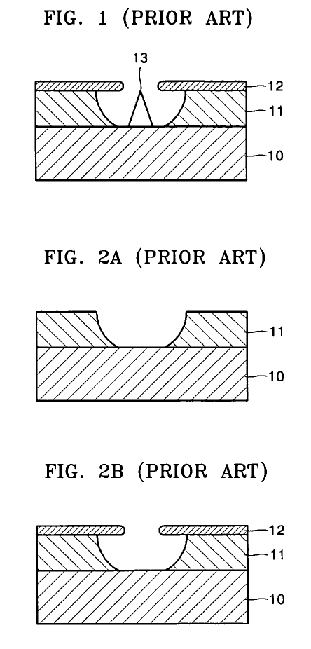

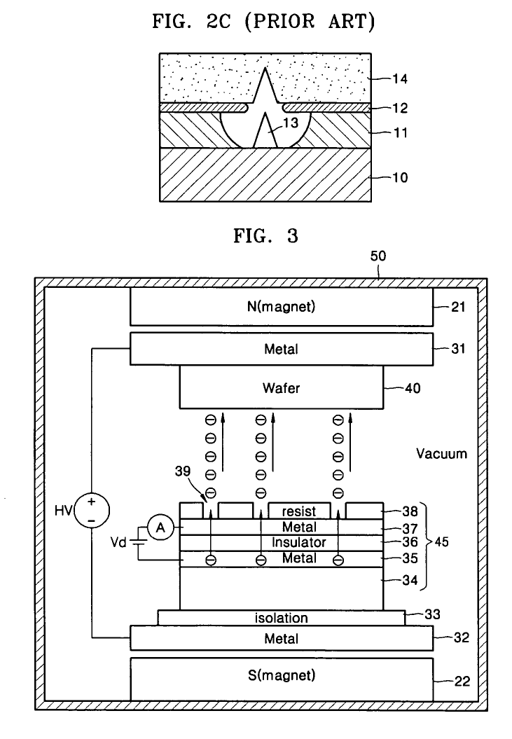

### DETAILED DESCRIPTION OF EXEMPLARY EMBODIMENTS

As described previously, a conventional emitter is formed by a complex semiconductor fabrication method. However, in the present invention, an emitter having a sharp tip is formed on the surface of a wafer by producing a strong arc and instantaneously melting the surface of the wafer.

FIG. 3 is a cross section of an apparatus for fabricating such an emitter using an arc according to an embodiment of the present invention. Referring to FIG. 3, in the apparatus, a device for producing an arc is installed inside a vacuum chamber 50, in which a vacuum is maintained.

In more detail, a first magnetic pole 21 on a ceiling of the vacuum chamber 50 and a second magnetic pole 22 on a floor of the vacuum chamber 50 are disposed to face each other. The first and second magnetic poles 21 and 22 may be a single bent magnet. It is also possible to install two separate magnets with different polarities in the vacuum chamber 50 to face each other. In the present embodiment, for example, the first magnetic pole 21 can be an N pole and the second magnetic pole 22 can be an S pole. A uniform magnetic field is formed inside the vacuum chamber 50 by the first and second magnetic poles 21 and 22, and thus electrons move around along the uniform magnetic field lines. Therefore, the first and second magnetic poles 21 and 22 constitute a magnetic field generating unit which provides an electron traveling path by the magnetic field created inside the vacuum chamber 50. The first and second magnetic poles 21 and 22 can be a permanent magnet or an electromagnet.

In addition, between the first and second magnetic poles 21 and 22, a first top electrode 31 and a first bottom electrode 32, which are electric field generating units for forming a uniform electric field, are installed facing each other at a predetermined distance. As shown in FIG. 3, a power source, which applies a relatively high voltage HV, is connected to the first top electrode 31 and the first bottom electrode 32. In such a structure, when the voltage is applied between the first top electrode 31 and the first bottom electrode 32, an electric field parallel to the magnetic field produced by the first and second magnetic poles 21 and 22 is formed between the first top electrode 31 and the first bottom electrode 32. Therefore, an arc can be generated by electrons emitted from a master emitter, which will be described later, traveling at a fast speed due to the magnetic field and the electric field produced inside the vacuum chamber 50.

A wafer 40, on the surface of which the emitter is to be fabricated, is inserted inside the vacuum chamber 50, and is, for example, located on the surface of the first top electrode 31 facing the first bottom electrode 32. The wafer 40 may be a silicon wafer. However, it is possible to use other types of materials instead of silicon depending on the purpose of the emitter to be fabricated. Meanwhile, an isolating material 33 is formed on the top surface of the first bottom electrode 32, and the master emitter 45 for emitting electrons is installed on the top surface of the isolating material 33. The isolating material 33 is for electrically insulating between the master emitter 45 and the first bottom electrode 32. In addition, the master emitter 45 emits electrons in a predetermined pattern, thereby forming emitters arranged in the predetermined pattern on the surface of the wafer 40.

As illustrated in FIG. 3, the master emitter 45 includes a substrate 34, a second bottom electrode 35, an insulating layer 36, a second top electrode 37, and a mask 38. The substrate 34 may be formed of silicon. Here, a power source, which applies a relatively low voltage Vd, is connected to the second bottom electrode 35 and the second top electrode 37. For example, the cathode of the power supply is connected to the second bottom electrode 35 and the anode of the power supply is connected to the second top electrode 37 so that electrons are emitted from the second bottom electrode 35 to the second top electrode 37. The insulating layer 36 electrically insulates the second bottom electrode 35 and the second top electrode 37. For example, openings 39 are formed on the mask 38 according to a predetermined pattern. The mask 38 can be made of photoresist and, and electrons can be emitted through the openings 39.

The method of fabricating the emitter using the apparatus having the above described structure next will be described.

First, the high voltage HV is applied between the first top electrode 32 and the first bottom electrode 32. For example, the positive voltage HV+ is applied to the first top electrode 31 and the negative voltage HV− is applied to the first bottom electrode 32. Then, the wafer 40 is charged by positive charges and a large number of positive charges gather at the surface of the wafer 40. Here, the voltage HV applied between the first top electrode 31 and the first bottom electrode 32 is maintained slightly lower than a breakdown voltage of vacuum inside the vacuum chamber 50. In the present embodiment, a value in the range of approximately 1-10 kV is appropriate when the distance between the wafer 40 and the mask 38 is in the range of approximately 1-100 mm.

At the same time, the voltage Vd is applied between the second bottom electrode 35 and the second top electrode 37. Here, if the negative voltage Vd− is applied to the second bottom electrode 35 and the positive voltage Vd+ is applied to the second top electrode 37, electrons are emitted from the second bottom electrode 35. If the insulating layer 36 is too thick, the electrons emitted from the second bottom electrode 35 cannot propagate towards the second top electrode 37. Therefore, the insulating layer 36 needs to be sufficiently thin. In the present embodiment, the thickness of the insulating layer 36 is preferably between approximately 5-30 nm. In addition, the thickness of the second bottom electrode 35 is preferably 10-500 nm and the thickness of the second top electrode 37 is preferably 1 approximately −20 nm.

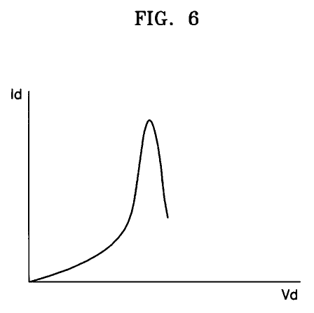

A schematic graph as shown in FIG. 6 illustrating the voltage-current characteristics can be produced when observing the current flowing between the second bottom electrode 35 and the second top electrode 37 while increasing the voltage Vd. That is, when the voltage Vd is low, the current slowly increases due to the resistance of the insulating layer 36. Then, when the voltage Vd surpasses a predetermined value, the number of electrons generated from the second bottom electrode 35 increases, and thus many electrons flow through the insulating layer 36 into the second top electrode 37, thereby forming a steep tilt in the voltage-current characteristics curve.

When the current reaches around 100-300 mA by continuously increasing the voltage Vd, a discharge occurs between the wafer 40 charged with positive charges of high voltage and the second top electrode 37. That is, an arc is generated. Then, most of the electrons propagate towards the wafer 40 due to the magnetic field produced by the first and second magnetic poles 21 and 22 and the electric field produced by the first top electrode 31 and the first bottom electrode 32. Therefore, as illustrated in FIG. 6, the current flowing between the second bottom electrode 35 and the second top electrode 37 drastically decreases. For example, when the distance between the wafer 40 and the mask 38 is approximately 2.3 nm, the voltage Vd when the discharge occurs between the wafer 40 and the second top electrode 37 is about 10V.

When the arc is formed between the wafer 40 and the second top electrode 37 as described above, many electrons collide with the surface of the wafer 40, which is charged with positive charges, thereby producing a high temperature. As a result, the surface of the wafer 40 to which the electrons collide instantaneously melts due to the high temperature. If the voltage Vd is maintained between the second bottom electrode 35 and the second top electrode 37, the surface of the wafer 40 is exposed to the high temperature for a long period of time, thereby damaging the surface of the wafer 40. Therefore, the voltage applied between the second bottom electrode 35 and the second top electrode 37 is removed immediately after the arc is produced. As described above, the creation of the arc can readily be detected through the change in the current flow between the second bottom electrode 35 and the second top electrode 37. In order to detect the change in the current, an amperemeter can be installed in the power source which provides the voltage to the second bottom electrode 35 and the second top electrode 37.

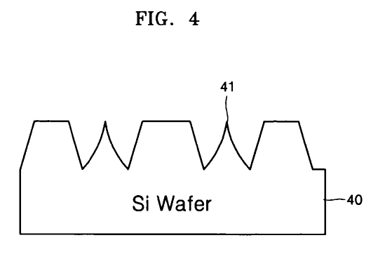

When the arc is produced only during a short period of time, the surface of the wafer 40 with which the electrons collide is instantaneously melted and then solidified. Consequently, an emitter 41 as illustrated in FIG. 4 is formed with a sharp tip at the center surrounded by a sunken area. Therefore, an ideal emitter can be readily formed using such an instantaneous discharge.

Meanwhile, when the mask 38 having the openings 39 patterned in the predetermined arrangement is formed on the surface of the second top electrode 37, the electrons are emitted through only the openings 39 of the mask 38 to the wafer 40. As a result, the emitters 41 are formed on the wafer 40 to correspond with the arrangement of the openings 39 of the mask 38. Therefore, according to the present invention, it is possible to fabricate a large number of emitters 41 in a desired arrangement by appropriately patterning the mask 38.

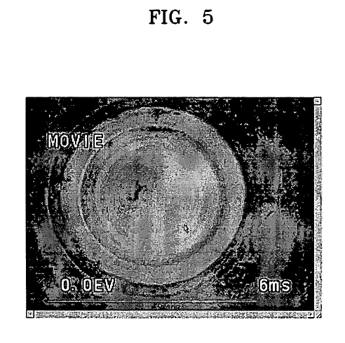

According to an embodiment of the present invention, the 10 nm voltage was applied between the first top electrode 31 and the first bottom electrode 32, and 10 V voltage was applied between the second bottom electrode 35 and the second top electrode 37. In addition, the distance between the wafer 40 and the mask 38 was 2.3 nm, the thickness of the insulating layer was 10 nm, and the diameter of the openings 39 was 4 nm. As a result, an emitter formed is illustrated in FIG. 5, and the diameter of the bottom surface of the emitter was about 50 nm and the diameter of the tip of the emitter was about 100 nm.

Therefore, it is possible to fabricate an emitter with an extremely sharp tip according to the present invention. The size of such an emitter can be controlled by, for example, the diameter of the openings 39 formed on the mask 38. Preferably, the diameter of the openings 39 is between approximately 100-200 nm.

A method of fabricating an emitter according to the present invention has been described. As described above, this method can produce the emitter more readily than the conventional method of fabricating an emitter. Therefore, fabrication costs and time can be reduced, and it is possible to mass produce the emitter due to the simplified production. In addition, it is possible to produce emitters having uniform nano-size tips. Consequently, the emitters fabricated according to the method of the present invention have highly satisfactory electron emitting characteristics, and thus can be used to advantage in FED devices for example.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An apparatus for fabricating an emitter using an arc, the apparatus comprising:
a vacuum chamber in which a wafer is inserted;
a magnetic field generating unit for generating a uniform magnetic field inside the vacuum chamber;
an electric field generating unit for forming an electric field parallel to the magnetic field inside the vacuum chamber; and
a master emitter for emitting electrons towards the wafer,
wherein the arc is generated by the electrons emitted from the master emitter in the magnetic field and the electric field, the arc making the surface of the wafer to instantaneously melt and solidify, thereby forming the emitter with a sharp tip on the surface of the wafer.

2. The apparatus of claim 1, wherein the magnetic field generating unit comprises:
a first magnetic pole disposed on the top portion of the vacuum chamber; and
a second magnetic pole having an opposite polarity to the first magnetic pole, disposed on the bottom portion of the vacuum chamber facing the first magnetic pole.

3. The apparatus of claim 1, wherein the electric field generating unit comprises:
a first top electrode and a first bottom electrode facing each other inside the magnetic field; and
a first power source for applying a voltage between the first top electrode and the first bottom electrode.

4. The apparatus of claim 3, wherein the first power source applies a voltage in the range of approximately 1-10 kV between the first top electrode and the first bottom electrode.

5. The apparatus of claim 3, wherein the wafer is disposed on surface of the first top electrode facing the first bottom electrode.

6. The apparatus of claim 3, wherein the master emitter comprises:
a substrate;
a second bottom electrode formed on the substrate;
an insulating layer formed on the second bottom electrode;
a second top electrode formed on the insulating layer;
a mask formed on the second top electrode; and
a second power source for applying a voltage between the second bottom electrode and the second top electrode.

7. The apparatus of claim 6, wherein a distance between the wafer and the mask is in the range of 1-100 mm.

8. The apparatus of claim 6, wherein at least one opening arranged in a predetermined form is patterned on the mask, and the electrons are emitted from the second top electrode via the at least one opening.

9. The apparatus of claim 6, wherein a thickness of the insulating layer is in the range of approximately 5-30 nm.

10. The apparatus of claim 6, wherein the master emitter is placed on top of the first bottom electrode, facing the wafer.

11. The apparatus of claim 10, wherein an isolating material is interposed between the master emitter and the first bottom electrode, thereby electrically insulating the master emitter and the first bottom electrode.

12. The apparatus of claim 6, wherein the level of the voltage applied between the second bottom electrode and the second top electrode is increased until the arc is formed between the wafer and the second top electrode, while voltage between the first top electrode and the first bottom electrode is maintained constant.

13. The apparatus of claim 12, further comprising an amperemeter for measuring a current between the second bottom electrode and the second top electrode to detect the creation of the arc.

14. A method of fabricating an emitter using an arc, comprising:
insulating a wafer inside a vacuum chamber;
forming a parallel electric field and a magnetic field inside the vacuum chamber;
emitting electrons from an electron emitting means towards the wafer inside the vacuum chamber; and
forming the emitter with a sharp tip on the surface of the wafer by instantaneously melting and solidifying the surface of the wafer by the arc generated by the movement of the electrons emitted from the electron emitting means in the magnetic field and the electric field.

15. The method of claim 14, wherein the magnetic field is formed by a first magnetic pole disposed at the top portion of the vacuum chamber and a second magnetic pole having an opposite polarity to the first magnetic pole, disposed at the bottom portion of the vacuum chamber facing the first magnetic pole.

16. The method of claim 14, wherein the electric field is formed by applying a voltage between a first top electrode and a first bottom electrode facing each other inside the magnetic field.

17. The method of claim 16, wherein a voltage in the range of approximately 1-10 kV is applied to the first top electrode and the first bottom electrode.

18. The method of claim 16, wherein the wafer is disposed on a surface of the first top electrode facing the first bottom electrode.

19. The method of claim 14, wherein the electron emitting means comprises:
a substrate;
a second bottom electrode formed on the substrate;
an insulating layer formed on the second bottom electrode, a second top electrode formed on the insulating layer;
a mask formed on the second top electrode; and
a second power source to apply voltage between the second bottom electrode and the second top electrode,
wherein the electron emitting means emits the electrons by applying voltage between the second bottom electrode and the second top electrode.

20. The method of claim 19, wherein at least one opening arranged in a predetermined form is patterned on the mask, and the electrons are emitted from the second top electrode via the at least one opening.

21. The method of claim 19, wherein the insulating layer has a thickness in the range of approximately 5-30 nm.

22. The method of claim 19, wherein the voltage applied to the second bottom electrode and the second top electrode is increased until the arc is formed between the wafer and the second top electrode.

23. The method of claim 22, wherein the applying of the voltage between the second bottom electrode and the second top electrode is stopped immediately after the arc is formed.

24. The method of claim 23, further comprising determining whether or not the arc is formed between the wafer and the second top electrode by observing the current flowing through the second bottom electrode and the second top electrode.
